(19) United States
(12) Patent Application Publication
(10) Pub. No.: US 2022/0376935 A1
(43) Pub. Date: Nov. 24, 2022

(54) Power over Ethernet system having multiple power source devices and power-good detection device thereof

(71) Applicant: IC Plus Corp., Hsinchu City (TW)

(72) Inventors: Chef HSIAO, Hsinchu City (TW); Daniel KUO, Hsinchu City (TW)

(21) Appl. No.: 17/386,611

(22) Filed: Jul. 28, 2021

(30) Foreign Application Priority Data
May 24, 2021 (TW) 110118668

(51) Int. Cl. H04L 12/10; G06F 1/28; G06F 1/26

(52) U.S. Cl. CPC H04L 12/10; G06F 1/28; G06F 1/266

(57) ABSTRACT

Power-good detection device for a PoE system with multiple power source devices having multiple power source devices comprises an input to connect multiple power source devices, power state detection circuit to measure power state signals received by the input and power-good threshold generation circuit to generate a threshold value in response to an input control signal. The power-good detection device determines a power-good (normal) and a failure state of the power source devices based on the threshold value and provides a power-good state signal.

### FIELD OF THE INVENTION

The invention relates to a power-over-Ethernet system, in particular to a power-good detection device to be used in the system. Specifically, the present invention relates to a power-over-Ethernet system having a plurality of power source devices, and a dynamic power-good detection device used in such a system.

### BACKGROUNDS OF THE INVENTION

### Prior Art

In a wired communication network, supplying electrical power to devices on the network through network cables is already a mature technology. For example, the Power-over-Ethernet (PoE) system, which is powered by the wiring of the Ethernet, has gradually become popular, due to its low installation costs and centralized power supply and power backup, and safety management. Currently most PoE systems follow the IEEE 802.3af-2003 standard, which is incorporated herein for reference.

The PoE system provides a scalable function, with which in the initial operation stage, the system can automatically or manually configure its power distribution to the limited number of ports in the system. As time passes, the system can also detect the power supply state automatically, and increase or decrease the number of communication ports to receive electrical power, based on the detection results in the power supply state. Each communication port is connectable by one power consuming device, to receive electrical power from the system.

There are methods to increase power supply in a PoE system. One of the methods is to use multiple power source devices or multiple groups of power supply. The plurality of power source devices is connected to one or more control elements in parallel, which control element then supplies or distributes the electrical power of the plural power source devices to individual power consuming devices in connection with the communication ports. Power source devices of non-PoE systems can also supply power to the PoE system, to increase its supplied power, as long as the sum of the PoE power and the non-PoE power can be distributed to one or more ports via the Ethernet wire/cables.

In a power supply system wherein a plurality of power source device is used, an important technical problem to be overcome is how to immediately stop supplying power to particular power consuming devices, i.e., to particular ports, when one or more of the plural power source devices shuts down or reduces its output power, in order to avoid the occurrence of overloading on the remaining supplied power. Further, in order to prevent impacts on the remaining power consuming devices due to a shutdown or low-power status, it is also necessary to stop supplying power to the particular power consuming devices immediately or within a very short time, usually within 20 ms, preferably within 2 ms. If the total power consumption of all the connected power consuming devices cannot be reduced within that period, the total system would just shut down.

FIG. 1 shows the block diagram of a PoE system with multiple power source devices. In FIG. 1 a conventional power-good detection device is also shown. As shown, the PoE system has 3 power source devices 101, 102, and 103. The power supply control chip 200 includes a power-good detection device 201 and a power distribution controller 202. In them, the input of the power-good detection device 201 is connected to the 3 power source devices 101, 102, 103, to receive the power state signals PG1, PG2, and PG3 of the 3 power source devices 101, 102, 103, and determines whether each of the power source devices 101, 102, 103 is supplying electrical power normally, according to the power state signals PG1 , PG2, PG3. The result of the determination is output in the form of a power-good state signal PGD1, PGD2, PGD3.

The power distribution controller 202 receives the power-good state signal PGD1, PGD2, PGD3 of the power-good detection device 201, and generates a power supply control signal, such as EN1-EN8, according to a predetermined power supply policy, followed by sending them to the communication ports Port N1 to Port N8. The power supply control signal is usually a switch signal used to turn ON or OFF the port switches of individual communication ports Port N1 to Port N8. The predetermined power supply policy is usually a preset rule that determines which of the communication ports Port N1 to Port N8 should be turned ON or OFF, when one or more power source device fails. Therefore, when the power-good detection device 201 determines that the power supply state of any of the power source devices 101, 102, 103 changes, for example, when a failure occurs or when a failure is repaired, it generates a power-good state signal PGD1, PGD2, and PGD3 to reflect the change. When the power distribution controller 202 receives the power-good state signal of the power-good detection device 201, it generates the power supply control signal EN1-EN8 and sent it to the communication ports Port N1 to Port N8, to change the ON/OFF state of the specific communication port.

As shown in the figure, the p power state signals PG1, PG2, and PG3 are generated by the branch circuits of the power source devices 101, 102, and 103. The detection points of the power state signals PG1, PG2, and PG3 are between the resistor pairs R11 and R12, R21 and R22, and R31 and R32, respectively. Therefore, the power state signals PG1, PG2, and PG3 are voltage signals and their values are:

PG1_V=HVpwr_1×[R12/(R11+R12)]

PG2_V=HVpwr_2×[R22/(R21+R22)]

PG3_V=HVpwr_3×(R32/(R31+R32)] (1)

wherein HVpwr is the voltage value of the power source devices 101, 102, 103.

According to the IEEE 802.3af/at standard, the regular voltage range for a PoE power source device is 57V to 44V.

Under this regulation, if the regular voltage of the power supplied by a power source device is set to 57V, the threshold (power-good) voltage value of PG1_V, PG2_V, and PG3_V should be about 1.390V, assuming that R11, R21 and R31 are 200KΩ, and R12, R22 and R32 are 5KΩ.

57V×[5KΩ/(5KΩ+200KΩ)]=1.390V

In this case, the power-good detection device 201 must set a power-good threshold value of 55V; when the voltage of the supplied power is below 55V, the power-good detection device 201 shall determine it as “failure,” because a power crash would take place, whenever the supplied voltage of a power source device is over 2V below its regular voltage value. To determine correctly, the power-good threshold value of the power state signals shall be set to 1.341V (55V ×[5KΩ/(5kΩ+200KΩ)]=1.341V). All power state signals with a detected voltage value equal to or higher than 1.341V would be determined as “power-good” (normal), whereby a signal (power-good state signal) representing a “power-good” state, such as 1, will be generated; otherwise, a signal representing a “failure” state, such as 0, will be generated. The combination of the determination of the power-good detection device 201 forms a power-good state signal.

However, this threshold value of 1.341V will cause a wrong decision, when the regular voltage of one of the power source devices is HVpwr=44V. As described above, the regular voltage of some PoE power source devices can be as low as 44V, in which case the PG1_V, PG2_V, and PG3_V values would be 1.073V (44V ×[5KΩ/(5KΩ+200KΩ)]=1.073V). For such power source devices, only when their supplied voltage is lower than 42V can the power-good detection device determine it is in a failure state. When this happens, the PG1_V, PG2_V, and PG3_V value would be 1.024V (42V×[5KΩ/(5KΩ+200KΩ)]=1.024V). However, because the power-good threshold value for power source device 101 was set to 1.341V, all the times power source device 101 will be determined as failure, no matter whether its supplied voltage falls into the regular range of voltage or not. The power-good detection device described above violates the IEEE 802.3af/at standard, which requires all PoE system to accept power source devices with a supplied voltage within the range of 57V to 44V.

Since the power-good state of the power source device cannot be detected correctly, the power supply policy cannot be adopted correctly to shutoff the switches of the communication port in time. As a result, the entire system will shut down.

The conventional art has proposed several solutions to this technical problem.

US patent publication US 2007/283173A1 disclosed a “system and method for detecting faults in an Ethernet power supply system”. In a PoE device whose operating range is set to 33 to 57 volts, using a booster diode with a 28-volt ride-through characteristic can produce an allowable error range of about 5 volts. Therefore, false alarms of power failure event detection can be prevented. A preferred embodiment selects booster diodes with different ride-through characteristics to combine between the ride-through voltage and the operating voltage range to provide a smaller or larger margin. In addition, diode circuits can also be used to achieve ride-through characteristics. The diode circuit includes a plurality of increasing diodes in series, a plurality of standard diodes or any combination thereof, so as to improve the accuracy of power failure detection.

U.S. Pat. No. 9,769,090 B2 disclosed “adjusting the current limit threshold based on the power demand of the powered device in the system to provide power through the communication link”. The invention controls the current limit according to the power demand of the PD. A current limit comparison table is provided to store the current limit thresholds corresponding to various PD power requirements. The threshold control circuit finds the corresponding limit value in the current limit comparison table based on the power required by the PD. The threshold control circuit can be applied to a system containing multiple power source devices.

From the observation in the above known technologies, it is known that the industry is in need of a novel multi-power Ethernet power supply system power-good detection device, which can dynamically set the power-good detection threshold according to the regular voltage value of the power source devices.

### SUMMARY OF THE INVENTION

The objective of the present invention is to provide a novel power-good detection device for a PoE system with multiple power source devices, which can dynamically set the power-good threshold value according to the specifications of the power source devices.

Another objective of the present invention is to provide a novel power-good detection device for a PoE system with multiple power source devices, which can correctly detect power failures and take appropriate measures in time.

The objective of the present invention is also to provide a PoE system with multiple power source devices with the above-mentioned power-good detection device.

According to the first aspect of the present invention, a power-good detection device for a PoE system with multiple power source devices is provided. The power-good detection device comprises:

a plurality of power state signal input terminals, each terminal to be electrically connected with at least one power source device, to receive a power state signal from the power source device; wherein the power state signal is preferably a voltage signal;

a power state detection circuit connected to the plurality of power state signal input terminals for receiving the power state signal and determining whether the power supply state of the corresponding power source device is in normal state, according to the power state signal; and

a power-good threshold generation circuit comprising a control signal input terminal for generating a power-good threshold value according to a control signal received at the control signal input terminal, and for providing the power-good threshold value to the power state detection circuit; wherein the power-good threshold value signal is preferably a voltage signal;

wherein, the power state detection circuit determines a power-good state of a power source device according to a corresponding power-good threshold value and generates a power-good state signal representing the determined power-good state. In a preferred embodiment of the present invention, the power-good state signal comprises a signal representing a normal status of a power source device and a signal representing failure status of a power source device.

In a particular preferred embodiment of the present invention, the power-good threshold generation circuit may include a programmable register and a digital-to-analog converter. The programmable register can generate a second control signal representing a threshold level and provide it to the digital-to-analog converter so that the digital-to-analog converter generates a corresponding power-good threshold value. In this embodiment, the threshold level may be one of 2, 4, 8, or 16 levels, or one of a multiple of 2 levels.

In addition, the input signal of the control signal input terminal can be provided to the control signal input terminal via any communication channel Applicable examples include any communication channel used in the conventional PoE system with multiple power source devices and can be an IIC bus, an EEPROM bus and so on.

In a specific preferred embodiment of the present invention, the power-good detection device may further comprise an optional encoding device connected to the back end of the power state detection circuit for converting the power supply state signal generated by the power state detection circuit into a code. The encoding device may also comprise a de-bounce circuit, to eliminate jitter noise in the power supply state signal.

In some preferred embodiments of the present invention, the power state detection circuit may comprise at least one comparator for generating a power-good state signal representing a normal or failure state of the power source devices according to a comparison result of the power-good threshold value and the input power state signal.

According to a second aspect, the present invention provides a PoE system with multiple power source devices, which comprises:

a plurality of power source devices;

a plurality of communication ports, each communication port to be connected by a power consuming device to establish a signal and power connection with the power consuming device; each communication port having a port switch to control a power supplied to the port;

a control device in connection with the plurality of power source devices and the plurality of communication ports via a network cable, to convert electrical power supplied by the respective power source device to electrical power usable by the power consuming device connected to each communication port, and to generate a power consumption control signal, to control power supplied to the communication port from the plurality of power source devices;

wherein the control device comprises one of the power-good detection devices for a PoE system with multiple power source devices described above; wherein the power-good detection device generates a power-good threshold value according to an input control signal and determines a power-good state according to the power-good threshold value, to generate a power-good state signal representing a normal or failure state of the plurality of power source devices; and

a power supply distribution controller for generating the power consumption control signal according to the power-good state signal.

Other objectives, features, and advantages of the present invention can be appreciated clearly from the detailed description of the preferred embodiments by referring to the drawings. It should be noted that the description of the embodiments of the present invention is only intended to illustrate the main technical content, features, and effects of the present invention, and is not intended to limit the scope of the present invention. It is obvious for the skilled persons in this industry to derive various changes and applications based on the description of the embodiments. As long as they do not depart from the scope of the attached patent claims, they are all within the scope of the present invention.

### BRIEF DESCRIPTION OF THE DRAWINGS

FIG. 1 shows the schematic diagram of a conventional PoE system with multiple power source devices.

FIG. 2 shows the schematic structural diagram of an embodiment of the power-good detection device for a PoE system with multiple power source devices of the present invention.

### DETAILED DESCRIPTION OF THE INVENTION

In the following, several embodiments of the PoE system with multiple power source devices and its power-good detection device of the present invention will be described by referring to the drawings, in order to demonstrate the technology, features and effects of the present invention.

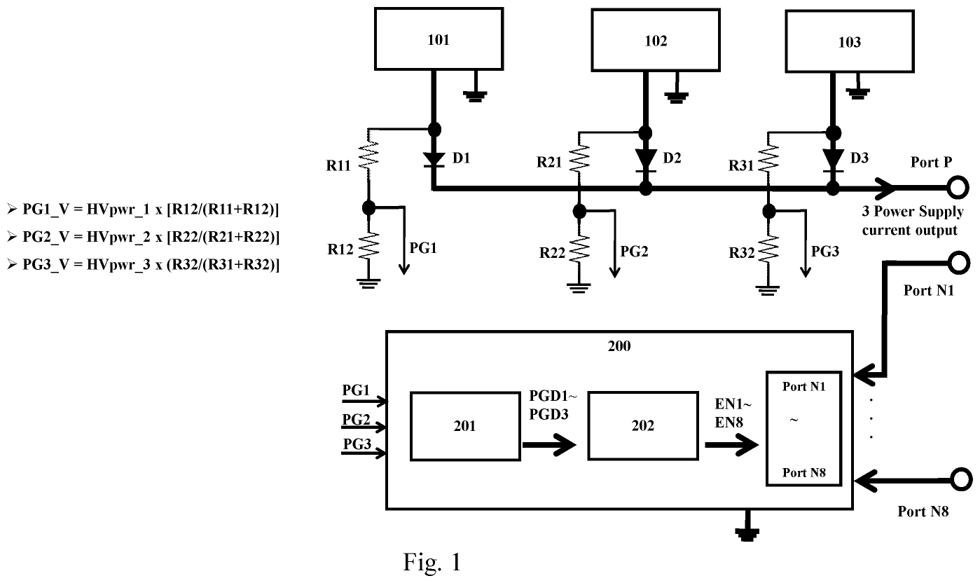

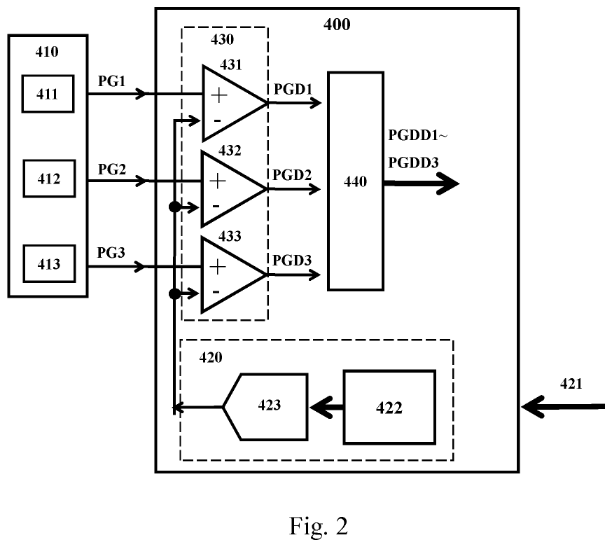

FIG. 2 shows a schematic structural diagram of an embodiment of the power-good detection device for a PoE system with multiple power source devices of the present invention. In the followings, the example shown in FIG. 2 will be used to illustrate the power-good detection device for a PoE system with multiple power source devices, as well as a PoE system with multiple power source devices wherein the invented power-good detection device is used. The power-good detection device 400 of FIG. 2 mainly replaces, or is an improvement of the power-good detection device 201 of FIG. 1, since they both generate power-good state signal PGD1, PGD2, PGD3.

As shown in FIG. 2, the power-good detection device 400 of the present invention mainly includes a power state signal input assembly 410, a power state detection circuit 430 connected to the power state signal input assembly 410, and a power-good threshold generation circuit 420 connected to the power state detection circuit 430 and an optional encoding device 440 connected to the power state detection circuit 430. Details thereof will be described in the followings.

The power state signal input assembly 410 provides a plurality of power status signal input terminals. The embodiment shown in FIG. 2 includes 3 power state signal input terminals 411, 412, and 413, each of which is provided for electrical connection with at least one power source device. As those skilled in the art can appreciate, the power-good detection device 400 of the present invention is used in the PoE system with multiple power source devices shown in FIG. 1, to determine whether each power source device is normally operating. Therefore, when the power-good detection device 400 is used in the invented PoE system with multiple power source devices, it provides the same functions of the power-good detection device 201 in FIG. 1, which are mainly to determine whether each power source device 101, 102, 103 is in normal operation. Therefore, the power state signal input assembly 410 of the power-good detection device 400 provides a plurality of power status signal input terminals 411, 412, 413 for connecting the 3 power source devices 101, 102, 103, to receive the power state signals PG1, PG2, PG3 of the 3 power source devices 101, 102, 103, and to determine whether each power source device is supplying electrical power normally, according to the features of the power state signals PG1, PG2, PG3. The result of the determination is output in the form of a power-good state signal PGD1, PGD2, and PGD3. Of course, the number of the power source devices that the power-good detection device 400 can include is not limited to 3. There can be less than or more than 3 power source devices.

In a preferred embodiment of the present invention, the power state signal may be a voltage signal. A method to implement such a voltage signal is shown in FIG. 1, wherein the power state signal PG1, PG2, and PG3 is branched out from the power lines of the power source devices 101, 102 and 103. The power state signal PG1, PG2, and PG3 is provided in the form of a voltage, and the voltage value is a ratio of the supply voltage of the corresponding power source devices 101, 102, 103, respectively. In other embodiments of the present invention, the power state signal PG1, PG2, PG3 may be a current or in another form of signals. In this embodiment of the present invention, a voltage signal is used for convenience.

The power state signal input terminals 411, 412, and 413 are conventional electrical connectors. It can also be a fixed contact, used to connect the power source devices 101, 102, 103, and introduce the power state signals PG1, PG2, PG3 of the power source devices 101, 102, 103 to the power state detection circuit 430.

The power state detection circuit 430 is connected to the plurality of power state signal input terminals 411, 412, 413 for receiving the power state signal PG1, PG2, and PG3, whereby to determine whether each corresponding power source device 101, 102, 103 is in normal operation, based on the power state signals PG1, PG2, and PG3. The result of the determination is output in the form of a power supply status signal PGD1, PGD2, PGD3. As shown in FIG. 2, an implementation of the power state detection circuit 430 is by comparators 431, 432, and 433. The two inputs of each comparator 431, 432, and 433 are respectively the power supply state signal PGD1, PGD2, and PGD3, and the power-good threshold value generated by the power-good threshold generation circuit 420. The method for the determination may be, when the value of any one of the power supply state signal PGD1, PGD2, PGD3 is higher than the threshold, it is determined that the corresponding power source device is in normal state; otherwise, it is in a failure state. Specifically, the power supply state signal PGD1, PGD2, PGD3 is preferably a voltage signal. At the same time, the threshold is also a voltage value. When the voltage value of any power supply status signal PGD1, PGD2, PGD3 is higher than the threshold value, the corresponding comparator 431, 432, 433 will output a signal with the value of 1 (or 0), which means that the corresponding power source device is in normal operation. Otherwise, a signal with the value of 0 (or 1 ) is output, which means that the corresponding power source device is in failure state.

Of course, other method to determine the power-good state of a power source device according to a threshold and to generate the power-good state signal PGD1, PGD2, PGD3 can also be applied to the present invention.

In order to dynamically adjusting the power-good threshold value, the power-good threshold generation circuit 420 provides a control signal input terminal 421 for receiving a first control signal from the external. The input terminal 421 can be any electrical connector, or an electrical contact, connected to any applicable signal channel to receive the first control signal. The signal channel can be any communication channel used in the conventional PoE system with multiple power source devices, such as an IIC bus, an EEPROM bus, etc. Other communication channels can also be used to provide the first control signal.

In a particularly preferred embodiment of the present invention, the power-good threshold generation circuit 420 may include a programmable register 422 and a digital-to-analog converter 423. The programmable register 422 can generate a second control signal representing a threshold level corresponding to the first control signal, and provide it to the digital-to-analog converter 423, so that the digital-to-analog converter 423 generates a corresponding power-good threshold value.

For example, the threshold level can be one of 2, 4, 8 or 16 levels, or one of a multiple of 2 levels. If a 16-level threshold is to be generated, the programmable register 422 can be a 4-bit programmable register, storing a value of from 0-15, representing the 16-level threshold. After receiving the second control signal, the programmable register 422 sends a corresponding numerical signal to the digital-to-analog converter 423, which can be also a 4-bit digital-to-analog converter, and generates a corresponding voltage according to the value of the level.

In detail, as mentioned earlier, the IEEE PoE standard stipulates that the regular range of power supply voltage HVpwr is 44V-57V. Accordingly, in the example shown in FIG. 1, if a dynamic threshold is to be provided, the threshold should be distributed between 1.073V-1.390V. If the range is equally divided into 16 levels, the voltage difference between each level should be:

(1.390V−1.073V)/16=0.317V/16=19.8 mV

The digital-to-analog converter 423 generates a threshold voltage of 1.073V+(0.0198V*N), wherein N is the value of the first control signal, and provides it to the comparators 431, 432, and 433.

Therefore, as long as a correct first control signal is generated according to the distribution of the regular operating voltage range of the power source devices 101, 102, 103 and provided to the power-good threshold generation circuit 420, the power-good detection device 400 can correctly determine the power-good state of the power source devices.

In this embodiment, a voltage signal is used as the threshold signal, mainly because the power state signal PG1, PG2, and PG3 is also a voltage signal. In other embodiments of the present invention, the threshold signal is not limited to a voltage signal.

In a specific preferred embodiment of the present invention, the power-good detection device 400 may further include an encoding device 440, connected to the back end of the power state detection circuit 430, to compile the power supply state signal PGD1, PGD2, PGD3 of the power state detection circuit 430 into a code. For example, if the power supply status signal PGD1, PGD2, PGD3 is 1, 1, 0, the encoding device 440 can generate a corresponding code of 1100 or 0110, to act as a control signal of the power distribution controller 202 of the PoE system with multiple power source devices. The encoding device may also include a de-bounce circuit (not shown) to eliminate jitter noise in the power supply state signal.

As mentioned above, by simply providing a power-good threshold generation circuit 420, such as that comprising a programmable register 422 and a digital-to-analog converter 423, the power-good detection device for a PoE system with multiple power source devices of the present invention can achieve correct determination of the power-good state of power source devices of various specifications.

The power-good detection device can be used in any known PoE system with multiple power source devices that comprises:

a plurality of power source devices;

a plurality of communication ports, each communication port to be connected by a power consuming device to establish a signal and power connection with the power consuming device; each communication port having a port switch to control a power supplied to the port;

a control device in connection with the plurality of power source devices and the plurality of communication ports via a network cable, to convert electrical power supplied by the respective power source device to electrical power usable by the power consuming device connected to each communication port, and to generate a power consumption control signal, to control power supplied to the communication port from the plurality of power source devices;

wherein the control device comprises one of the power-good detection devices described above; and

a power supply distribution controller for generating the power consumption control signal according to the power-good state signal.

What is claimed is:

1. A power-good detection device for a PoE system with multiple power source devices, comprising:
a plurality of power state signal input terminals, each terminal to be electrically connected with at least one power source device, to receive a power state signal from the power source device;
a power state detection circuit connected to the plurality of power state signal input terminals for receiving the power state signal and determining whether the power supply state of the corresponding power source device is in normal state, according to the power state signal; and
a power-good threshold generation circuit comprising a control signal input terminal for generating a power-good threshold value according to a control signal received at the control signal input terminal, and for providing the power-good threshold value to the power state detection circuit;
wherein, the power state detection circuit determines a power-good state of a power source device according to a corresponding power-good threshold value and generates a power-good state signal representing the determined power-good state.

2. The power-good detection device for a PoE system with multiple power source devices of claim 1, wherein the power-good state signal comprises a signal representing a normal status of a power source device and a signal representing failure status of a power source device.

3. The power-good detection device for a PoE system with multiple power source devices of claim 1, wherein the power state detection circuit comprises at least one comparator, to generate the power-good state signal according to an input power-good threshold value and an input power state signal.

4. The power-good detection device for a PoE system with multiple power source devices of claim 1, wherein the power state signal is a voltage signal and the power-good threshold value signal is a voltage signal.

5. The power-good detection device for a PoE system with multiple power source devices of claim 3, wherein the power state signal is a voltage signal and the power-good threshold value signal is a voltage signal.

6. The power-good detection device for a PoE system with multiple power source devices of claim 1, wherein the power-good threshold generation circuit may include a programmable register and a digital-to-analog converter.

7. The power-good detection device for a PoE system with multiple power source devices of claim 6, wherein the programmable register generates a second control signal representing a threshold level and provide it to the digital-to-analog converter so that the digital-to-analog converter generates a corresponding power-good threshold value.

8. The power-good detection device for a PoE system with multiple power source devices of claim 7, wherein the threshold level is one of 2, 4, 8, or 16 levels, or one of a multiple of 2 levels.

9. The power-good detection device for a PoE system with multiple power source devices of claim 1, wherein the input signal is provided to the control signal input terminal via an IIC bus or an EEPROM bus.

10. The power-good detection device for a PoE system with multiple power source devices of claim 1, wherein the power-good detection device further comprises an optional encoding device connected to the back end of the power state detection circuit for converting the power supply state signal generated by the power state detection circuit into a code.

11. The power-good detection device for a PoE system with multiple power source devices of claim 1, wherein the encoding device further comprises a de-bounce circuit, to eliminate jitter noise in the power supply state signal.

12. A PoE system with multiple power source devices, comprising:
a plurality of power source devices;
a plurality of communication ports, each communication port to be connected by a power consuming device to establish a signal and power connection with the power consuming device; each communication port having a port switch to control a power supplied to the port;
a control device in connection with the plurality of power source devices and the plurality of communication ports via a network cable, to convert electrical power supplied by the respective power source device to electrical power usable by the power consuming device connected to each communication port, and to generate a power consumption control signal, to control power supplied to the communication port from the plurality of power source devices;
wherein the control device comprises the power-good detection devices for a PoE system with multiple power source devices of any of claims 1-11;
wherein the power-good detection device generates a power-good threshold value according to an input control signal and determines a power-good state according to the power-good threshold value, to generate a power-good state signal representing a normal or failure state of the plurality of power source devices; and
a power supply distribution controller for generating the power consumption control signal according to the power-good state signal.
